(19) United States
(12) Patent Application Publication
(10) Pub. No.: US 2013/0062102 A1
(43) Pub. Date: Mar. 14, 2013

(54) DOUBLE-SIDED FLEXIBLE PRINTED CIRCUIT BOARD AND METHOD OF MANUFACTURING THE SAME

(71) Applicants: Sung Won Lee, Seoul (KR); Jae Beum Kim, Seoul (KR); Hwa Jin Kim, Seoul (KR)

(72) Inventors: Sung Won Lee, Seoul (KR); Jae Beum Kim, Seoul (KR); Hwa Jin Kim, Seoul (KR)

(73) Assignee: LG INNOTEK CO., LTD., Seoul (KR)

(21) Appl. No.: 13/697,246

(22) PCT Filed: Jul. 19, 2010
(86) PCT No.: PCT/KR2010/004689

§ 371 Date: Nov. 27, 2012

(30) Foreign Application Priority Data
May 11, 2010 (KR) 10-2010-0043896

(51) Int. Cl. H05K 1/03; H05K 3/06

(52) U.S. Cl. 174/254; 216/13; 216/20

(57) ABSTRACT

The present invention relates to a double-sided flexible printed circuit board in which circuit patterns are formed, including an insulating substrate, conduction layers sputtered on both sides of the insulating substrate, a through hole formed to connect circuits formed in the both sides, seed layers formed on the conduction layers of the both sides, and pattern plating layers formed on an inner wall of the through hole and on the respective seed layers, and a method of manufacturing the same. Accordingly, the loss of a circuit width can be minimized because a sputtering-type material not an adhesive is used between the insulating substrate and the thin copper (Cu) layer. Further, productivity can be improved because a roll-to-roll process can be used. In addition, the thickness of a circuit can be controlled and micro circuit patterns can be formed because a semi-additive method is used.

### TECHNICAL FIELD

The present invention relates to a double-sided flexible printed circuit board and a method of manufacturing the same, in which micro circuits are formed using a sputtering-type material.

### BACKGROUND ART

In general, a flexible printed circuit board (FPCB) is used to electrically connect two sections in portions having lots of bends in several electronic and mechanical fields. Major characteristics of the flexible printed circuit board include excellent flexibility, light weight, and a small size. Accordingly, with the recent development of electronic components and component built-in technology and a reduction in the weight, thickness, and size of electronic products, there is a growing demand for a flexible printed circuit board. Further, with a rapid development of the degree of integration of semiconductor integrated circuits, the surface mounting technology for mounting a small-sized chip and a component thereof has been developed. Accordingly, there is a growing need for a flexible printed circuit board which facilitates built-in components even in the complicated and narrow space. In particular, with the development of technologies, such as mobile phones, LCD panels, and PDPs, the use of a flexible printed circuit board having a both-sided structure, facilitating an increase in the density of circuits, is rapidly increasing and thus there is a growing demand for the development of manufacturing technologies thereof.

FIG. 1 is a flowchart illustrating a process of manufacturing a conventional flexible printed circuit board. Referring to FIG. 1, a through hole for electrical connection is formed in a cut flexible copper lamination sheet, forming a thin copper (Cu) layer, using a penetration drill in upper and lower surfaces. Electrical copper (Cu) plating is performed on the entire surface of the copper lamination sheet, thereby forming an electroless copper (Cu) plating layer. Electrical copper (Cu) plating is again performed on the electroless copper (Cu) plating layer so that an electrical copper (Cu) plating layer is formed on the entire surface of a substrate including the portions of the through hole. After a substrate cleaning process is performed, a dry film is laminated. Next, an exposure process using ultraviolet rays, a development process using a developer, and an etching process using an etchant are performed, thereby forming circuits on both sides of the substrate. Finally, the dry film remaining on the surface of the substrate is delaminated. Accordingly, a flexible printed circuit board is completed. However, a conventional method of manufacturing a both-sided flexible printed circuit board is difficult to implement micro circuits because the circuits are formed by etching a mass-production both-sided FCCL (Cu: 12 μm, 9 μm). That is, there is a limitation to the implementation of micro circuits using the thickness of copper (Cu), used for mass production, because of the isotropy of etching.

### DISCLOSURE OF INVENTION

### Technical Problem

Accordingly, the present invention has been made in view of the above problems, and it is an object of the present invention to provide a double-sided flexible printed circuit board and a method of manufacturing the same, in which the loss of a circuit width can be minimized and the thickness of a circuit can be controlled using a sputtering-type material, thereby being capable of forming micro circuit patterns.

### Technical Solution

To achieve the above object, according to an embodiment of the present invention, there is provided a double-sided flexible printed circuit board in which circuit patterns are formed, including an insulating substrate, conduction layers sputtered on both sides of the insulating substrate, a through hole formed to connect circuits formed in the both sides, seed layers formed on the conduction layers of the both sides, and pattern plating layers formed on an inner wall of the through hole and on the respective seed layers. Accordingly, the loss of a circuit width can be minimized and thus micro circuit patterns can be formed.

In particular, the insulating substrate can be formed of a polyimide film.

Further, the conduction layer can include a first conduction layer made of nickel (Ni) or chromium (Cr) and a second conduction layer made of copper (Cu).

Further, it is preferred that the first conduction layer be formed in a thickness range of 1 Å to 200 Å and the second conduction layer be formed in a thickness range of 1 Å to 2000 Å.

Moreover, the seed layer can be made of copper (Cu).

In particular, is preferred that the copper (Cu) seed layer be formed in a thickness range of 0.1 μm to 3 μm.

The double-sided flexible printed circuit board can further include protection films adhered on exposed portions of the pattern plating layers on the both sides in order to protect the circuits.

According to another embodiment of the present invention, there is provided a method of manufacturing the double-sided flexible printed circuit board, including the steps of (A) forming conduction layers on both sides of an insulating substrate, (B) forming a through hole in order to connect circuits formed in the both sides, (C) stacking seed layers on the conduction layers of the both sides, and (D) performing pattern plating on an inner wall of the through hole and on the seed layers using a pattern plating resist and then forming circuit patterns through delamination and etching. Accordingly, the thickness of a circuit can be controlled and micro circuit patterns can be formed.

In particular, the step (A) can include the steps of (A-1) forming a first conduction layer by sputtering nickel (Ni) or chromium (Cr) and (A-2) forming a second conduction layer by sputtering copper (Cu).

Further, preferably, in the step (A-1), the first conduction layer is formed in a thickness range of 1 Å to 200 Å, and in the step (A-2), the second conduction layer is formed in a thickness range of 1 Å to 2000 Å.

Further, in the step (C), preferably, the seed layer is laminated using copper (Cu) in a thickness range of 0.1 μm to 3 μm.

The method can further include the step of (E) adhering protection films for protecting the circuit patterns on the both sides after the step (D).

### Advantageous Effects

In accordance with the present invention, a sputtering-type material not an adhesive is used between an insulating substrate and a thin copper (Cu) layer. Accordingly, the loss of a circuit width can be minimized and productivity can be improved because a roll-to-roll process can be used. Further, since a semi-additive process is used, the thickness of a circuit can be controlled and micro circuit patterns can be formed.

### BRIEF DESCRIPTION OF DRAWINGS

FIG. 1 is a flowchart illustrating a process of manufacturing a conventional flexible printed circuit board;

FIG. 2 is a cross-sectional view of a double-sided flexible printed circuit board according to an embodiment of the present invention; and

FIG. 3 is a cross-sectional view showing a process of manufacturing the double-sided flexible printed circuit board according to an embodiment of the present invention.

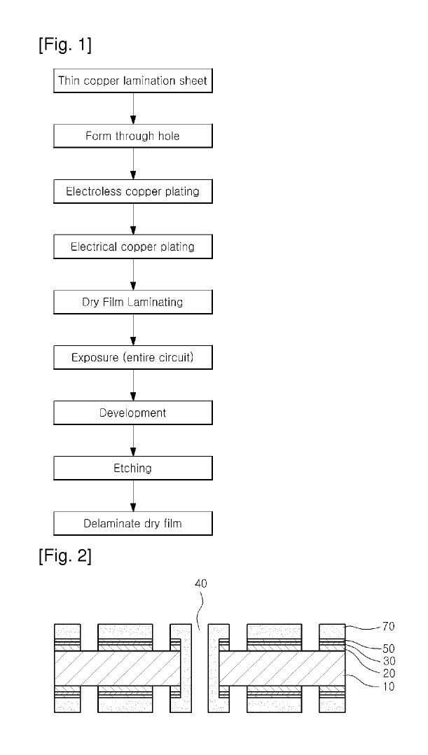

### MODE FOR THE INVENTION

Hereinafter, some exemplary embodiments of the present invention will be described in detail with reference to the accompanying drawings. However, the present invention is not limited to the disclosed embodiments, but may be implemented in various ways. The present embodiments are provided to complete the disclosure of the present invention and to allow those having ordinary skill in the art to understand the scope of the present invention. The shapes, etc., of constituent elements in the drawings may be enlarged in order to highlight clearer descriptions thereof. The same reference numbers are used throughout the drawings to refer to the same parts.

FIG. 2 is a cross-sectional view of a double-sided flexible printed circuit board according to an embodiment of the present invention. Referring to FIG. 2, the double-sided flexible printed circuit board in which circuit patterns are formed includes conduction layers 20 and 30 and a seed layer 50 sequentially formed on each of the both sides of an insulating substrate 10, a through hole 40 formed to connect circuits formed on both sides, and pattern plating layers 70 sequentially formed on the inner walls of the seed layers 50 and the through hole 40. Here, it is preferred that the insulating substrate 10 as a base substrate be formed of a polyimide film.

The conduction layers 20 and 30 are formed on both sides of the insulating substrate 10 through sputtering. It is preferred that the conduction layers 20 and 30 include a first conduction layer 20 made of nickel (Ni) or chromium (Cr) and a second conduction layer 30 made of copper (Cu). Here, the first conduction layer 20 preferably is formed in a thickness range of 1 Å to 200 Å, and the second conduction layer 30 preferably is formed in a thickness range of 1 Å to 2000 Å. Since the first conduction layer 20 is formed using a sputtering-type material of a low profile not an adhesive as described above, the loss of a circuit width can be reduced and the seed layer 50 made of copper (Cu) can be formed at a thickness of 3 μm or less. Accordingly, the thickness of a circuit can be controlled and micro circuit patterns can be formed.

Further, it is preferred that the seed layer 50 formed over the conduction layers 20 and 30 be made of copper (Cu) and formed, in particularly, in a thickness range of 0.1 μm to 3 μm. As described above, the copper (Cu) seed layer 50 of 3 μm in thickness can be formed using a sputtering-type material. The pattern plating layers 70 in which the circuit patterns are formed are formed on the inner wall of the through hole 40 and on the respective seed layers 50 using a resist for pattern plating. Although not shown, it is preferred that protection films 80 be adhered on the pattern plating layers 70 in order to protect the circuit patterns.

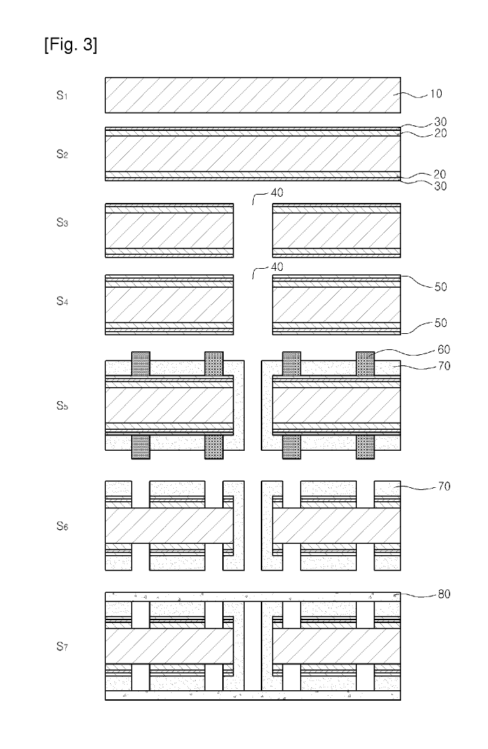

FIG. 3 is a cross-sectional view showing a process of manufacturing the double-sided flexible printed circuit board according to an embodiment of the present invention. Referring to FIG. 3, the insulating substrate 10 is prepared at step S1. It is preferred that the insulating substrate 10 be a polyimide film.

Next, the conduction layers 20 and 30 are formed on both sides of the insulating substrate 10 through sputtering at step S2. The first conduction layer 20, made of nickel (Ni) or chromium (Cr) and configured to function as an adhesive layer, and the second conduction layer 30 made of copper (Cu) are sequentially formed. It is preferred that the first conduction layer 20 be formed in a thickness range of 1 Å to 200 Å and the second conduction layer 30 be formed in a thickness range of 1 Å to 2000 Å. As described above, since the first conduction layer 20 is made of the sputtering-type material of a low profile not an adhesive, the copper (Cu) seed layer can be formed at a thickness of 3 μm or less.

Next, the through hole 40 is formed in order to connect circuits formed on both sides at step S3. The seed layers 50 are laminated over the conduction layers 20 and 30 on the both sides at step S4. It is preferred that the seed layer 50 be formed of a copper (Cu) seed layer in a thickness range of 0.1 μm to 3 μm. Next, a resist 60 for pattern plating is formed on the inner wall of the through hole 40 and on the copper (Cu) seed layers 50. Pattern plating 70 for forming the circuits is performed at a thickness of 15 μm or less at step S5. After the pattern plating 70, circuit patterns are formed through delamination and etching, thereby completing the double-sided flexible printed circuit board at step S6. In this case, after the circuit patterns are formed, the protection films 80 for protecting the circuits can be further adhered on both sides at step S7. As described above, since the sputtering-type material is used, the loss of a circuit width can be minimized and a roll-to-roll process can be used. Accordingly, productivity can be improved. Further, since a semi-additive method is used, the thickness of a circuit can be controlled and micro circuit patterns can be formed.

While the present invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A double-sided flexible printed circuit board in which circuit patterns are formed, comprising:
an insulating substrate;
conduction layers sputtered on both sides of the insulating substrate;
a through hole formed to connect circuits formed in the both sides;
seed layers formed on the conduction layers of the both sides; and
pattern plating layers formed on an inner wall of the through hole and on the respective seed layers.

2. The double-sided flexible printed circuit board of claim 1, wherein the insulating substrate is a polyimide film.

3. The double-sided flexible printed circuit board of claim 1, wherein the conduction layers comprise:
a first conduction layer made of nickel (Ni) or chromium (Cr); and
a second conduction layer made of copper (Cu).

4. The double-sided flexible printed circuit board of claim 3, wherein the first conduction layer is formed in a thickness range of 1 Å to 200 Å.

5. The double-sided flexible printed circuit board of claim 3, wherein the second conduction layer is formed in a thickness range of 1 Å to 2000 Å.

6. The double-sided flexible printed circuit board of claim 1, wherein the seed layer is a copper (Cu) seed layer.

7. The double-sided flexible printed circuit board of claim 6, wherein the copper (Cu) seed layer is formed in a thickness range of 0.1 μm to 3 μm.

8. The double-sided flexible printed circuit board of claim 1, further comprising protection films adhered on exposed portions of the pattern plating layers on the both sides in order to protect the circuits.

9. A method of manufacturing a double-sided flexible printed circuit board, the method comprising the steps of:
(A) forming conduction layers on both sides of an insulating substrate;
(B) forming a through hole in order to connect circuits formed in the both sides;
(C) stacking seed layers on the conduction layers of the both sides; and
(D) performing pattern plating on an inner wall of the through hole and on the seed layers using a pattern plating resist and then forming circuit patterns through delamination and etching.

10. The method of claim 9, wherein the step (A) comprises the steps of:
(A-1) forming a first conduction layer by sputtering nickel (Ni) or chromium (Cr); and
(A-2) forming a second conduction layer by sputtering copper (Cu).

11. The method of claim 10, wherein:
in the step (A-1), the first conduction layer is formed in a thickness range of 1 Å to 200 Å, and
in the step (A-2), the second conduction layer is formed in a thickness range of 1 Å to 2000 Å.

12. The method of claim 9, wherein in the step (C), the seed layer is laminated using copper (Cu) in a thickness range of 0.1 μm to 3 μm.

13. The method of claim 9, further comprising (E) adhering protection films for protecting the circuit patterns on the both sides after the step (D).
